(19) United States
(12) Patent Application Publication
(10) Pub. No.: US 2019/0334513 A1
(43) Pub. Date: Oct. 31, 2019

(54) LOW NOISE COMPARATOR

(71) Applicant: QUALCOMM Incorporated, San Diego, CA (US)

(72) Inventor: Edward Wai Yeung Liu, San Diego, CA (US)

(21) Appl. No.: 15/963,042

(22) Filed: Apr. 25, 2018

(51) Int. Cl. H03K 5/1252; H03K 5/24

(52) U.S. Cl. CPC H03K 5/1252; H04B 1/40; H03K 5/2481

(57) ABSTRACT

A successive approximation register analog-to-digital converter (SAR ADC) includes a comparator with low input referred noise that uses a small capacitor array for improved communication speed. The comparator includes a cross-coupled pair of transistors, a first input transistor, a second input transistor, a first negative capacitance device and a second negative capacitance device. The first and second transistors are in a differential configuration. A gate of the first input transistor is coupled to a first array of capacitors and a gate of the second input transistor is coupled to a second array of capacitors. The first negative capacitance device is coupled between the gate of the first input transistor and a first polarity node. The second negative capacitance device is coupled between the gate of the second input transistor and a second polarity node.

### TECHNICAL FIELD

The present disclosure generally relates to analog-to-digital converters. More specifically, the present disclosure relates to a low noise comparator for a high speed successive approximation register analog-to-digital converter.

### BACKGROUND

A wireless device (e.g., a cellular phone or a smartphone) in a wireless communication system may transmit and receive data for two-way communication. In the process, the data signals communicated may be converted from an analog signal to a digital signal and vice versa.

An analog-to-digital converter (ADC) that employs a successive approximation register (SAR), referred to as a “SAR ADC,” converts a continuous analog input signal into a discrete digital representation of the analog input signal. The SAR ADC executes binary search operations by comparing, at each iteration, the analog input signal against a threshold determined as part of the binary search operations. The SAR ADC generates a digital bit (at logic zero or at logic one) at each iteration based on the result of the comparison.

SAR ADCs are widely used in various applications that may specify low power and area efficient ADCs. Many SAR ADCs use a capacitor array (e.g., a binary weighted capacitor array) and a comparator (e.g., a single path comparator, a two-path comparator, a three-path comparator, a four-path comparator, or an N-path comparator). Comparator noise, however, is a major issue in high-speed SAR ADC design.

### SUMMARY

A comparator includes a cross-coupled pair of transistors including a first polarity node (e.g., positive gain node or terminal) and a second polarity node (e.g., negative gain node). The first polarity is different than the second polarity. The comparator also includes a first input transistor and a second input transistor arranged in a differential configuration. A gate of the first input transistor is coupled to a first array of capacitors. A gate of the second input transistor is coupled to a second array of capacitors. The comparator further includes a first negative capacitance device coupled between the gate of the first input transistor and the first polarity node. Furthermore, the comparator includes a second negative capacitance device coupled between the gate of the second input transistor and the second polarity node.

In yet another aspect of the present disclosure, a comparator includes a cross-coupled pair of transistors including a first polarity node and a second polarity node. The first polarity is different than the second polarity. The comparator also includes a first input transistor and a second input transistor arranged in a differential configuration. A gate of the first input transistor is coupled to a first array of capacitors. A gate of the second input transistor is coupled to a second array of capacitors. The comparator further includes means for generating a first negative capacitance. The first negative capacitance generating means is coupled between the gate of the first input transistor and the first polarity node. Furthermore, the comparator includes means for generating a second negative capacitance. The second negative capacitance generating means is coupled between the gate of the second input transistor and the second polarity node.

A noise reduction method for a comparator may include generating a first negative capacitance between a first polarity node associated with a cross-coupled pair of transistors and a first differential input of the comparator. The method also includes generating a second negative capacitance between a second polarity node associated with the cross-coupled pair of transistors and a second differential input of the comparator. The first polarity is different than the second polarity. The method further includes cancelling an unwanted input capacitance of the comparator by the first negative capacitance and the second negative capacitance.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a wireless device communicating with a wireless communication system.

FIG. 2 shows a block diagram of the wireless device in FIG. 1, according to an aspect of the present disclosure.

FIG. 3 is a circuit diagram of a successive approximation register analog-to-digital converter (SAR ADC) in accordance with aspects of the present disclosure.

FIG. 4 illustrates an exemplary differential comparator according to aspects of the present disclosure.

FIG. 5 illustrates an exemplary differential comparator including negative capacitance devices according to aspects of the present disclosure.

FIG. 6 illustrates a small signal schematic diagram of a circuit of the differential comparator of FIG. 5 including negative capacitance devices (e.g., negative capacitors).

FIG. 7 illustrates another exemplary differential comparator including negative capacitance devices according to aspects of the present disclosure.

FIG. 8 depicts a simplified flowchart of a noise reduction method for a comparator of a successive approximation register analog-to-digital converter.

FIG. 9 is a block diagram showing an exemplary wireless communication system in which a configuration of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

Many successive approximation register analog-to-digital converters (SAR ADCs) use a capacitor array (e.g., a binary weighted capacitor array) and a comparator (e.g., a single path comparator, a two-path comparator, a three-path comparator, a four-path comparator, or an N-path comparator). Comparator noise, however, is a major issue in high speed SAR ADC design. The comparator noise may include input referred noise. Input referred noise is a noise voltage or current that, when applied to an input of a noiseless circuit, generates a same output noise as the actual circuit does. Thus, it is desirable to achieve low input referred noise for a comparator in a high speed SAR ADC. It is also desirable to achieve a small capacitor array for improved communication speed so that the SAR ADC settles as fast as possible. However, input referred noise is high when referred through a small capacitor array. For example, an increase in the input referred noise for the comparator is based on an insertion loss of a capacitive divider formed by an input capacitance of the comparator and the capacitor array.

One technique for reducing the input referred noise at the input of the comparator is to increase the width/length ratio of an input device (e.g., transistor) of the comparator. However, a large input device or an input device with an increased width/length ratio slows down the comparator due to a larger input capacitance and increased insertion loss. To reduce or improve the insertion loss, the size of the capacitor array can be increased. However, large capacitor arrays have parasitic capacitance that slows down the comparator.

Aspects of the present disclosure improve the noise issue of SAR ADCs and their corresponding comparators. For example, aspects of the present disclosure are directed to a successive approximation register analog-to-digital converter (SAR ADC) including a comparator with reduced or low input referred noise that uses a small capacitor array for improved communication speed. The comparator may include a cross-coupled pair of transistors with a first polarity node (e.g., a positive gain node) and a second polarity node (e.g., a negative gain node). The comparator may be a differential comparator that includes a first device to generate a first negative capacitance (e.g., a first negative capacitance device) for a first path of the differential comparator. The differential comparator may also include a second device to generate a second negative capacitance (e.g., a second negative capacitance device) for a second path of the differential comparator.

The first negative capacitance device and the second negative capacitance device cancel out an unwanted input capacitance of the comparator. For example, the first negative capacitance device cancels a first input capacitance of a first input transistor and the second negative capacitance device cancels a second input capacitance of a second input transistor. The unwanted input capacitance may be a gate-to-source capacitance of the first input transistor and/or the second input transistor. The first negative capacitance device and the second negative capacitance device may be adjustable capacitance devices. The first negative capacitance device and the second negative capacitance device may be adjusted based on equations described below (e.g., equation 3). The adjusted value of the first negative capacitance device and the second negative capacitance device may be finalized, optimized or verified based on simulation. Various capacitor tuning techniques based on capacitor banks or varactors are also possible. However, matching specifications are not stringent to achieve good noise reduction. Thus, a simple procedure to fix the negative capacitor value suffices.

In some aspects, the first input transistor and the second input transistor include a p-type metal oxide semiconductor (PMOS) transistor, an n-type metal oxide semiconductor (NMOS) transistor, or a combination of both. The first negative capacitance device and/or the second negative capacitance device may be a metal oxide semiconductor (MOS) capacitor, a metal insulator metal capacitor (MIMCAP), a metal oxide metal capacitor (MOMCAP) or any additional circuitry or connectivity that results in a negative capacitance. For example, the MOS capacitor can be a metal oxide semiconductor varactor (MOSVAR).

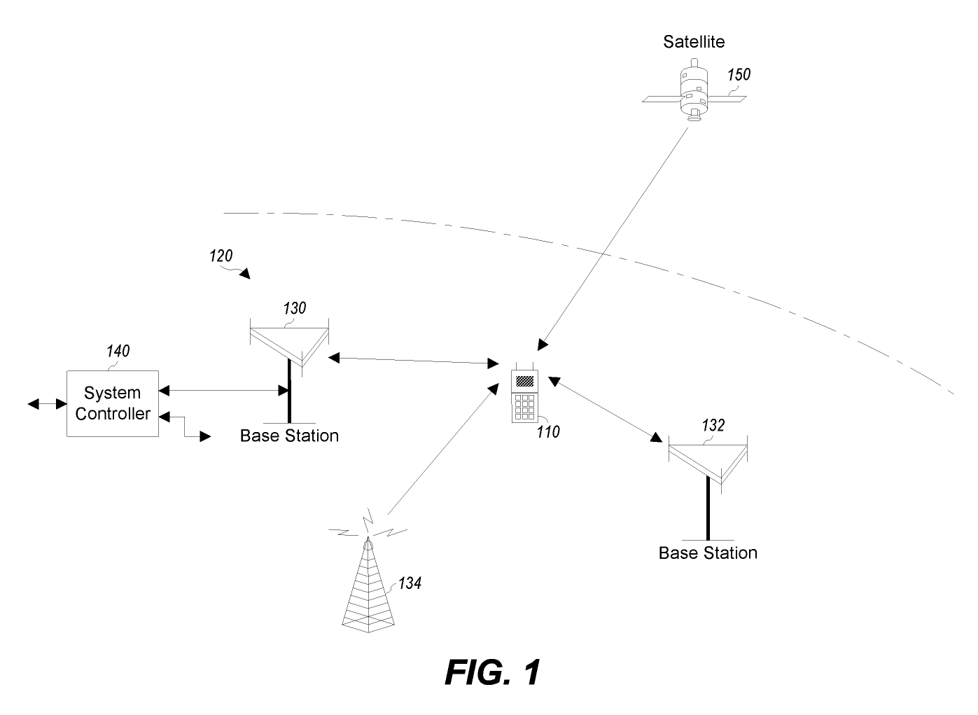

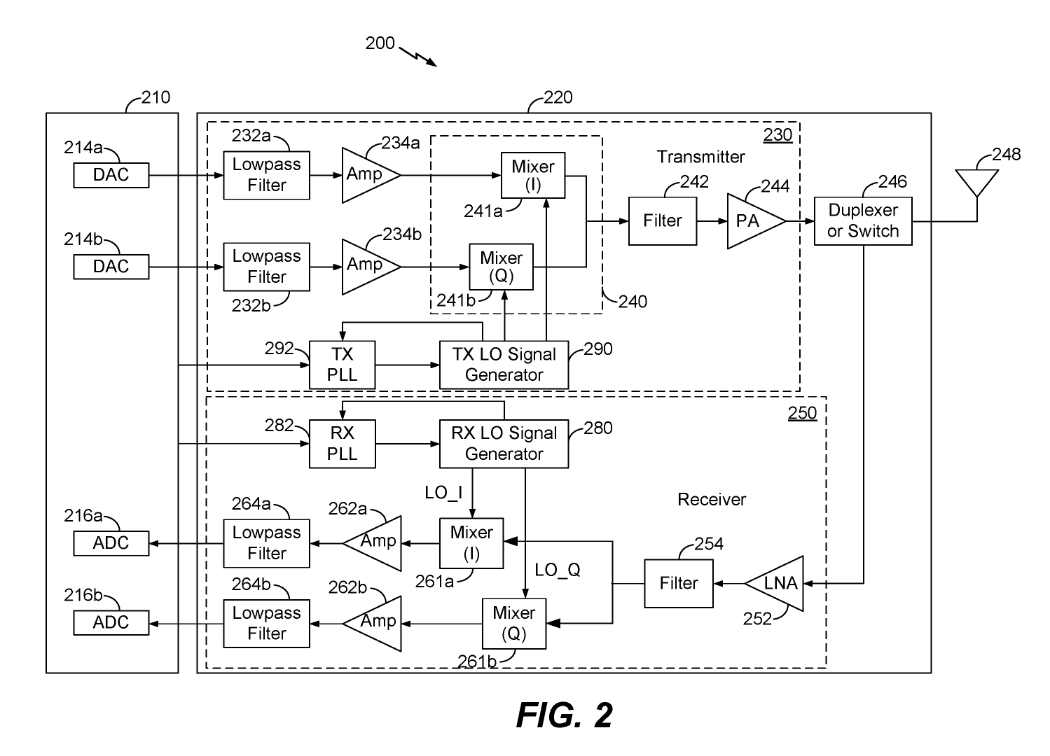

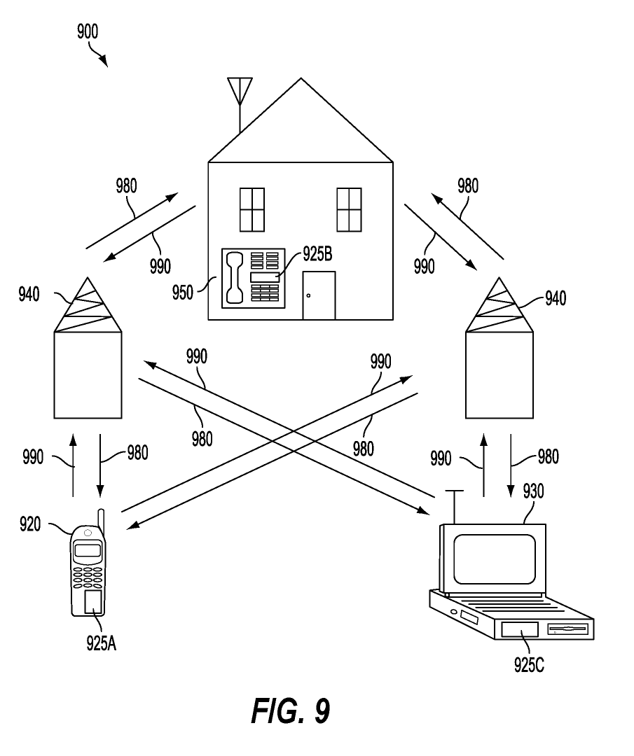

The aspects of the present disclosure may be implemented in the system of FIGS. 1 and 9. More specifically, aspects of the present disclosure may be implemented in the wireless device of FIG. 2.

FIG. 1 shows a wireless device 110, including a comparator, communicating with a wireless communication system 120. The wireless communication system 120 may be a 5G system, a long term evolution (LTE) system, a code division multiple access (CDMA) system, a global system for mobile communications (GSM) system, a wireless local area network (WLAN) system, millimeter wave (mrnW) technology, or some other wireless system. A CDMA system may implement wideband CDMA (WCDMA), time division synchronous CDMA (TD-SCDMA), CDMA2000, or some other version of CDMA. In a millimeter wave (mmW) system, multiple antennas are used for beamforming (e.g., in the range of 30 GHz, 60 GHz, etc.). For simplicity, FIG. 1 shows the wireless communication system 120 including two base stations 130 and 132 and one system controller 140. In general, a wireless system may include any number of base stations and any number of network entities.

A wireless device 110 may be referred to as a user equipment (UE), a mobile station, a terminal, an access terminal, a subscriber unit, a station, etc. The wireless device 110 may also be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. The wireless device 110 may be capable of communicating with the wireless communication system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communication such as 5G, LTE, CDMA2000, WCDMA, TD-SCDMA, GSM, 802.11, etc.

The wireless device 110 may support carrier aggregation, which is operation on multiple carriers. Carrier aggregation may also be referred to as multi-carrier operation. According to an aspect of the present disclosure, the wireless device 110 may be able to operate in low-band from 698 to 960 megahertz (MHz), mid-band from 1475 to 2170 MHz, and/or high-band from 2300 to 2690 MHz, ultra-high-band from 3400 to 3800 MHz, and long term evolution (LTE) in LTE unlicensed bands (LTE-U/LAA) from 5150 MHz to 5950 MHz. Low-band, mid-band, high-band, ultra-high-band, and LTE-U refer to five groups of bands (or band groups), with each band group including a number of frequency bands (or simply, “bands”). For example, in some systems each band may cover up to 200 MHz and may include one or more carriers. For example, each carrier may cover up to 40 MHz in LTE. Of course, the range for each of the bands is merely exemplary and not limiting, and other frequency ranges may be used. LTE Release 11 supports 35 bands, which are referred to as LTE/UMTS bands and are listed in 3GPP TS 36.101. The wireless device 110 may be configured with up to five carriers in one or two bands in LTE Release 11.

FIG. 2 shows a block diagram of an exemplary design of a wireless device 200, such as the wireless device 110 shown in FIG. 1. FIG. 2 shows an example of a transceiver 220, which may be a wireless transceiver (WTR). In general, the conditioning of the signals in a transmitter 230 and a receiver 250 may be performed by one or more stages of amplifier(s), filter(s), upconverters, downconverters, and the like. These circuit blocks may be arranged differently from the configuration shown in FIG. 2. Furthermore, other circuit blocks not shown in FIG. 2 may also be used to condition the signals in the transmitter 230 and receiver 250. Unless otherwise noted, any signal in FIG. 2, or any other illustrations in the drawings, may be either single-ended or differential. Some circuit blocks in FIG. 2 may also be omitted.

In the example shown in FIG. 2, the wireless device 200 generally includes the transceiver 220 and a data processor 210. The data processor 210 may include a memory (not shown) to store data and program codes, and may generally include analog and digital processing elements. The transceiver 220 may include the transmitter 230 and receiver 250 that support bi-directional communication. In general, the wireless device 200 may include any number of transmitters and/or receivers for any number of communication systems and frequency bands. All or a portion of the transceiver 220 may be implemented on one or more analog integrated circuits (ICs), radio frequency (RF) integrated circuits (RFICs), mixed-signal ICs, and the like.

A transmitter or a receiver may be implemented with a super-heterodyne architecture or a direct-conversion architecture. In the super-heterodyne architecture, a signal is frequency-converted between radio frequency and baseband in multiple stages, e.g., from radio frequency to an intermediate frequency (IF) in one stage, and from intermediate frequency to baseband in another stage for a receiver. In the direct-conversion architecture, a signal is frequency-converted between radio frequency and baseband in one stage. The super-heterodyne and direct-conversion architectures may use different circuit blocks and/or have different requirements. In the example shown in FIG. 2, the transmitter 230 and the receiver 250 are implemented with the direct-conversion architecture.

In a transmit path, the data processor 210 processes data to be transmitted. The data processor 210 also provides in-phase (I) and quadrature (Q) analog output signals to the transmitter 230 in the transmit path. In an exemplary aspect, the data processor 210 includes digital-to-analog converters (DACs) 214a and 214b for converting digital signals generated by the data processor 210 into the in-phase (I) and quadrature (Q) analog output signals (e.g., I and Q output currents) for further processing.

Within the transmitter 230, low-pass filters 232a and 232b filter the in-phase (I) and quadrature (Q) analog transmit signals, respectively, to reduce undesired images caused by the prior digital-to-analog conversion. Amplifiers (Amp) 234a and 234b amplify the signals from low-pass filters 232a and 232b, respectively, and provide in-phase (I) and quadrature (Q) baseband signals. An upconverter 240 including upconversion mixers 241a and 241b upconverts the in-phase (I) and quadrature (Q) baseband signals with in-phase (I) and quadrature (Q) transmit (TX) local oscillator (LO) signals from a TX LO signal generator 290 to provide an upconverted signal. A filter 242 filters the upconverted signal to reduce undesired images caused by the frequency upconversion as well as interference in a receive frequency band. A power amplifier (PA) 244 amplifies the signal from filter 242 to obtain the desired output power level and provides a transmit radio frequency signal. The transmit radio frequency signal is routed through a duplexer/switch 246 and transmitted via an antenna 248.

In a receive path, the antenna 248 receives communication signals and provides a received radio frequency (RF) signal, which is routed through the duplexer/switch 246 and provided to a low noise amplifier (LNA) 252. The duplexer/switch 246 is designed to operate with a specific receive (RX) to transmit (TX) (RX-to-TX) duplexer frequency separation, such that RX signals are isolated from TX signals. The received RF signal is amplified by the LNA 252 and filtered by a filter 254 to obtain a desired RF input signal. Downconversion mixers 261a and 261b mix the output of the filter 254 with in-phase (I) and quadrature (Q) receive (RX) LO signals (i.e., LO_I and LO_Q) from an RX LO signal generator 280 to generate in-phase (I) and quadrature (Q) baseband signals. The in-phase (I) and quadrature (Q) baseband signals are amplified by amplifiers 262a and 262b and further filtered by low-pass filters 264a and 264b to obtain in-phase (I) and quadrature (Q) analog input signals, which are provided to the data processor 210. In the exemplary configuration shown, the data processor 210 includes analog-to-digital converters (ADCs) 216a and 216b for converting the analog input signals into digital signals for further processing by the data processor 210.

In FIG. 2, the transmit local oscillator (TX LO) signal generator 290 generates the in-phase (I) and quadrature (Q) TX LO signals used for frequency upconversion, while a receive local oscillator (RX LO) signal generator 280 generates the in-phase (I) and quadrature (Q) RX LO signals used for frequency downconversion. Each LO signal is a periodic signal with a particular fundamental frequency. A phase locked loop (PLL) 292 receives timing information from the data processor 210 and generates a control signal used to adjust the frequency and/or phase of the TX LO signals from the TX LO signal generator 290. Similarly, a PLL 282 receives timing information from the data processor 210 and generates a control signal used to adjust the frequency and/or phase of the RX LO signals from the RX LO signal generator 280.

The wireless device 200 may support carrier aggregation and may (i) receive multiple downlink signals transmitted by one or more cells on multiple downlink carriers at different frequencies, and/or (ii) transmit multiple uplink signals to one or more cells on multiple uplink carriers. For intra-band carrier aggregation, the transmissions are sent on different carriers in the same band. For inter-band carrier aggregation, the transmissions are sent on multiple carriers in different bands. Those skilled in the art will understand, however, that aspects described herein may be implemented in systems, devices, and/or architectures that do not support carrier aggregation.

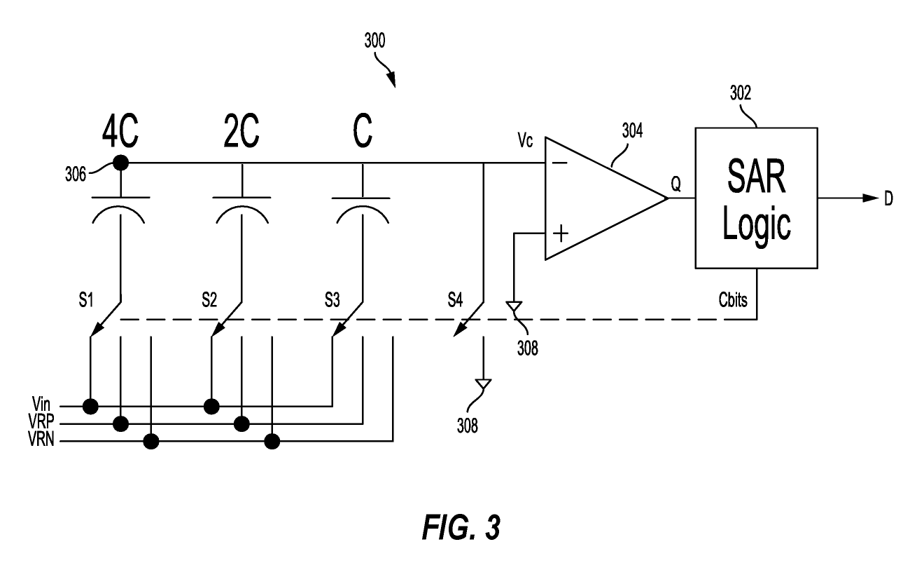

FIG. 3 is a circuit diagram of a successive approximation register analog-to-digital converter (SAR ADC) 300 in accordance with aspects of the present disclosure. The SAR ADC 300 converts an analog input signal Vin into digital output data D at an output of SAR logic 302, for example. In this aspect, the SAR ADC 300 uses a capacitive digital-to-analog converter (DAC). Capacitive DACs employ the principle of charge redistribution to generate an analog output voltage. The capacitive DAC includes an array of N capacitors with binary weighted values. For example, the capacitive DAC includes capacitors C, 2C, and 4C.

A first terminal of each of the capacitors C, 2C, and 4C is coupled or connected to a common circuit node 306. A second terminal of each of the capacitors C, 2C, and 4C is respectively coupled or connected to a first switch S1, a second switch S2, and a third switch S3. The first, second, and third switches S1, S2, and S3 selectively couple the second terminal of each of the capacitors C, 2C, and 4C to the input voltage Vin, a positive reference voltage VRP, or a negative reference voltage VRN. For example, the first switch S1 selectively couples the second terminal of the capacitor C to the input voltage Vin, the positive reference voltage VRP or the negative reference voltage VRN. The positive reference voltage VRP and the negative reference voltage VRN form a differential signal. The second switch S2 selectively couples the second terminal of the capacitor 2C to the input voltage Vin, the positive reference voltage VRP or the negative reference voltage VRN. The third switch S3 selectively couples the second terminal of the capacitor 4C to the input voltage Vin, the positive reference voltage VRP or the negative reference voltage VRN.

The analog input voltage Vin is sampled by the first, second, and third switches S1, S2, and S3 based on a clock signal and a conversion is started based on the clock signal. For example, during an acquisition phase, the common circuit node 306 at which all the capacitors C, 2C, and 4C share a connection, is connected to a ground 308 and the second terminals of each of the capacitors C, 2C, and 4C are connected to the input signal Vin. For example, a switch S4 selectively connects the common circuit node 306 to the ground 308.

The capacitive DAC is coupled or connected to a comparator 304. The comparator 304 compares a voltage V_{C} of the common circuit node 306 with the ground potential at the ground 308 and outputs a binary decision Q. The SAR logic 302 receives the binary decision Q and outputs control bits Cbits to control the switches S1, S2, S3, and S4. In some aspects, the SAR logic 302 may also generate a sampling signal (not shown). For example, for each switch (S1, S2, or S3), the second terminal of the corresponding capacitor (C, 2C, or 4C) is connected to the analog input signal Vin when the sampling signal is asserted. Otherwise, when the sampling signal is not asserted, the second terminal of the corresponding capacitor (C, 2C, or 4C) is connected to the positive reference voltage VRP or the negative reference voltage VRN. For example, the second terminal is connected to the positive reference voltage VRP when the sampling signal is not asserted and the corresponding control bit is one (1), and the second terminal is connected to the negative reference voltage VRN when the sampling signal is not asserted and the corresponding control bit is zero (0).

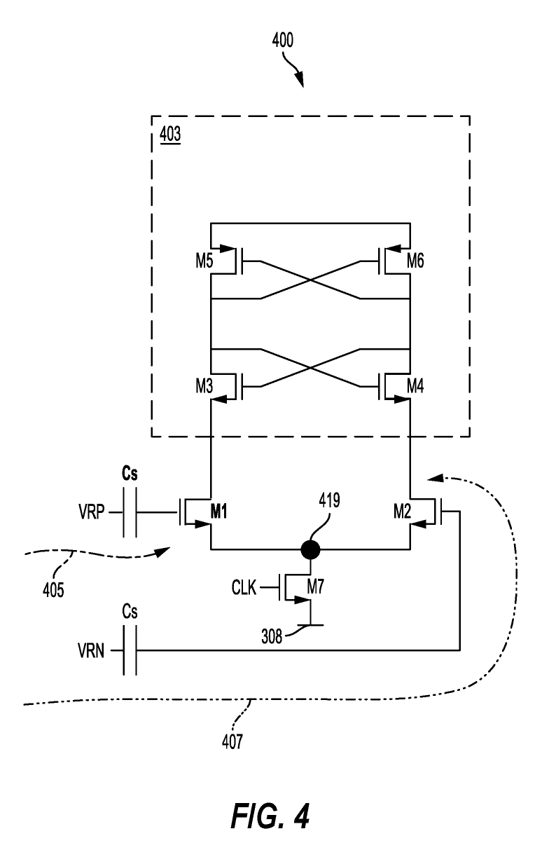

FIG. 4 illustrates an exemplary differential comparator 400. For illustrative purposes, some of the labelling and numbering of the devices and features of FIG. 4 are similar to those of FIG. 3. The comparator 400 may be similar to the comparator 304 of FIG. 3. For example, the comparator 400 may be part of a SAR ADC. The comparator 400 may generate a comparison result between two input signals (e.g., the positive reference voltage VRP and the negative reference voltage VRN are in series with the voltages stored on the capacitors Cs). A total positive voltage may be provided to a gate of a transistor M1 and a total negative voltage may be provided to a gate of a transistor M2. A drain of each of the transistor M1 and the transistor M2 is coupled to a set of cross-coupled pairs of transistors 403. The set of cross-coupled pairs of transistors 403 may include transistors M3, M4, M5, and M6. The transistors M1, M2, M3, and M4 may be n-type metal oxide semiconductor (NMOS) transistors while the transistors M5 and M6 are p-type metal oxide semiconductor (PMOS) transistors.

A source of each of the transistor M1 and the transistor M2 is coupled to a drain of a transistor M7. The transistor M7 is clocked by a clock signal CLK. For example, the transistor M7 receives the clock signal CLK and selectively sets a voltage level at a dynamic node 419 in response to receiving the clock signal CLK.

An array of N capacitors may be represented by capacitors Cs in each of a first differential path 405 and a second differential path 407 of the differential comparator 400. In one aspect, the capacitors or capacitor array Cs may be separate from the comparator 400, but part of the SAR ADC 300. In other aspects, the capacitor array Cs may be part of the comparator 400. The positive reference voltage VRP and the negative reference voltage VRN may be provided by a differential reference source (not shown).

It is desirable to achieve low input referred noise for a comparator in a high speed SAR ADC. It is also desirable to achieve a small capacitor array for improved communication speed. However, input referred noise is high when referred through a small capacitor array. For example, the increase in the input referred noise for the comparator 400 is based on an insertion loss of a capacitive divider formed by a gate-to-source capacitance Cgs1 (of each of the transistor M1 and the transistor M2) and the capacitor array Cs of the first differential path 405 and the second differential path 407.

Considering the transistor M1, the capacitive divider function corresponds to:

Vgs1/VRP=Cs/(Cs+Cgs1), 1

where Cgs1 is a gate-to-source capacitance of the transistor M1 and Vgs1 is a gate-to-source voltage of the transistor M1.

Accordingly, an input referred noise at VRP/VRN is higher by as much as (1+Cgs1/Cs) due to an insertion loss of the capacitive divider.

To reduce the input referred noise at the input of the differential comparator 400, a width/length ratio of the transistor M1 and the transistor M2 may be increased. The increased width/length ratio of the transistor M1 and the transistor M2, however, slows down the differential comparator 400 and increases insertion loss (1+Cgs1/Cs) of the differential comparator 400. To reduce the insertion loss, the size of the capacitor array Cs can be increased. However, the large capacitor array Cs increases parasitic capacitance that slows down the differential comparator 400.

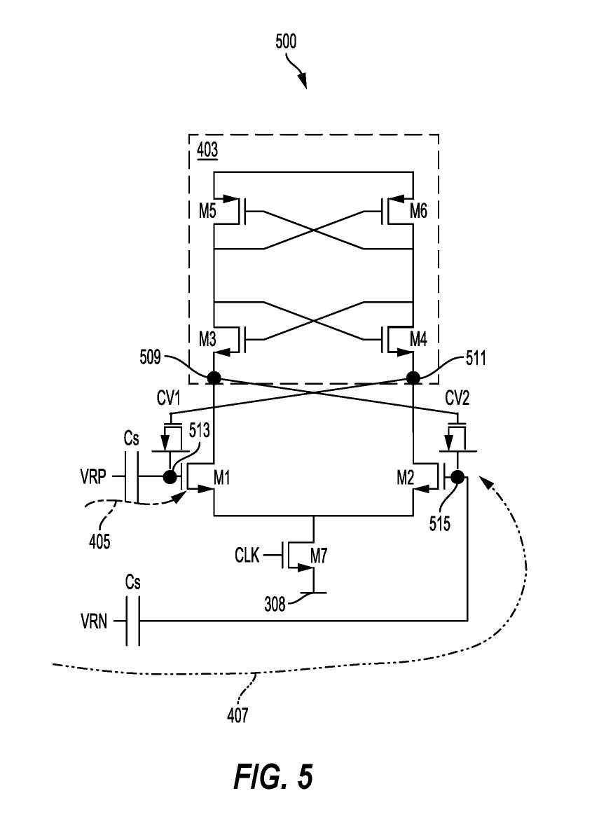

FIG. 5 illustrates an exemplary differential comparator 500 including negative capacitance devices according to aspects of the present disclosure. For illustrative purposes, some of the labelling and numbering of the devices and features of FIG. 5 is similar to those of FIGS. 3 and 4. FIG. 5, however, introduces a first negative capacitance and a second negative capacitance in the first differential path 405 and the second differential path 407. For example, the first negative capacitance is achieved by a first metal oxide semiconductor (MOS) varactor CV1 (e.g., a fixed capacitor). The second negative capacitance is achieved by a second metal oxide semiconductor (MOS) varactor CV2.

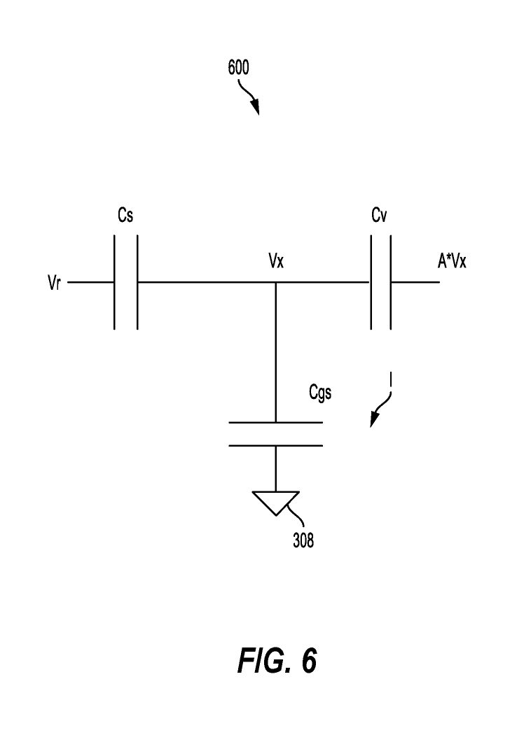

The differential comparator 500 includes the set of cross-coupled pairs of transistors 403, which includes a first polarity node 509 (e.g., a positive gain node) and a second polarity node 511 (e.g., a negative gain node). The first MOS varactor CV1 is between a first differential input 513 of the differential comparator 500 and the second polarity node 511 in a positive feedback configuration. The second MOS varactor CV2 is between a second differential input 515 of the differential comparator 500 and the first polarity node 509 in a positive feedback configuration. The gain node has a gain applied to its input before being propagated to its output. The applied gain may be positive or negative. For example, the gain may correspond to voltage gain A*Vx achieved across the MOS varactor Cv, as illustrated in FIG. 6.

In operation, the first MOS varactor CV1 generates a first negative capacitance to cancel out unwanted input capacitance at the first differential input 513. The second MOS varactor CV2 generates a second negative capacitance to cancel out unwanted input capacitance at the second differential input 515. The cancellation of the unwanted input capacitance reduces insertion loss to zero according to equation 3.

FIG. 6 illustrates a small signal schematic diagram of a circuit 600 of the differential comparator 500 including negative capacitors. For illustrative purposes, some of the labelling and numbering of the devices and features of FIG. 6 is similar to those of FIGS. 3, 4 and 5. The circuit 600 includes a reference voltage Vr (e.g., the positive reference voltage VRP and/or the negative reference voltage VRN), the array of N capacitors represented by the capacitor array Cs, a gate voltage Vx, and the gate-to-source capacitance Cgs of the transistor M1 and/or the transistor M2. The circuit 600 also includes a MOS varactor Cv (e.g., the first MOS varactor CV1 and/or the second MOS varactor CV2) to achieve the negative capacitance, and a voltage gain A*Vx achieved across the MOS varactor Cv and at least one of the cross-coupled pairs of transistors (e.g., 403). Current (I) to charge a gate-to-source capacitance Cgs of the transistor M1 and/or the transistor M2 comes from the MOS varactor Cv. When the gate-to-source capacitance Cgs is effectively cancelled by the negative capacitance, all the current to charge the gate-to-source capacitance Cgs comes from current (I), and no current comes through the capacitor array Cs. No current through the capacitor array Cs implies there is no voltage drop, and Vx is identical to Vr. As a result, the insertion loss is effectively zero.

A capacitive divider is formed by the gate-to-source capacitance Cgs and the capacitor array Cs. Taking the gate voltage of the transistor (e.g., the transistor M1 or the transistor M2) as a function of the reference voltage Vr, a ratio of the gate voltage Vx to the reference voltage Vr is represented as follows:

Vx/Vr=Cs/(Cs+Cgs+(1−A)Cv), 2

where A is gain value at the right hand side terminal of the negative capacitor.

To reduce or even eliminate insertion loss, the goal is to make the ratio Vx/Vr unity. If capacitor array Cs is very small, then the signal through the divider is very small, so the loss is large. If noise is a factor at the gate of the transistor M1 or M2, then the input referred noise through the capacitor array Cs is increased. For example, the input referred noise may be higher by (1+Cgs/Cs) due to the insertion loss of the capacitive divider. This increase in noise reduces the goal of achieving a ratio of unity (e.g., zero loss) as illustrated as follows:

Vx/Vr=Cs/Cs=1 3

To achieve the ratio of unity, the gate-to-source capacitance should be as small as possible or cancelled by a negative capacitance so that an input capacitance of zero is achieved. For example, the ratio of unity may be achieved when a negative capacitor Cv equal to Cgs/(A−1) is applied.

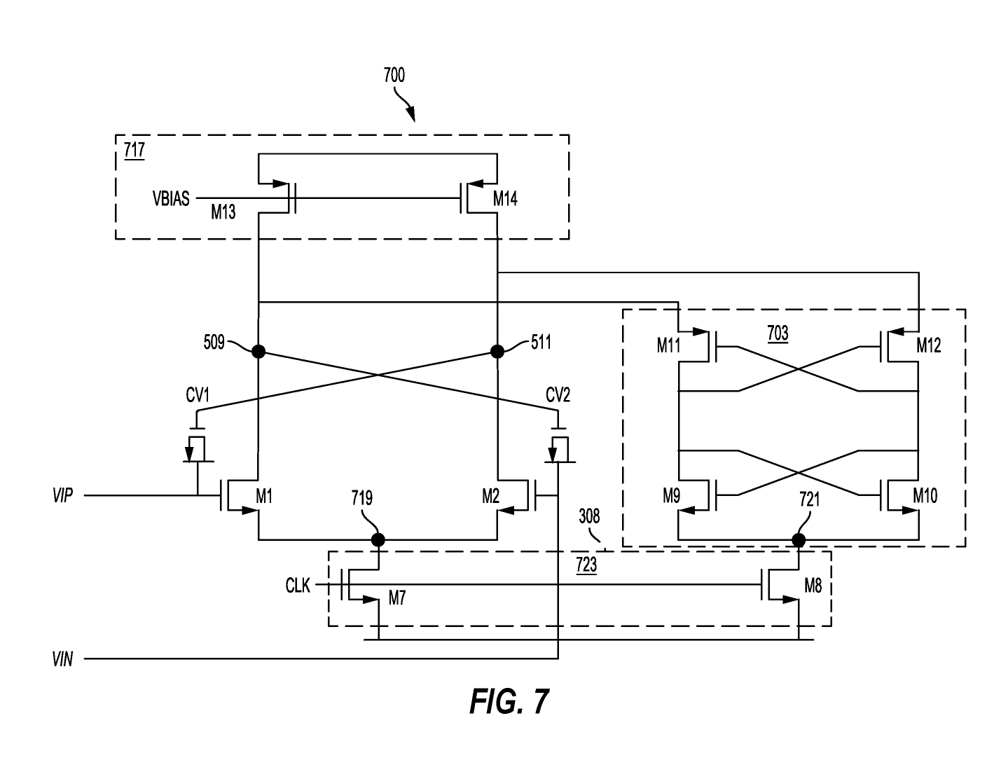

FIG. 7 illustrates another exemplary differential comparator 700 including negative capacitance devices according to aspects of the present disclosure. For illustrative purposes, some of the labelling and numbering of the devices and features of FIG. 7 is similar to those of FIGS. 3, 4 and 5.

The differential comparator 700 includes a charge circuit 717 coupled to the first polarity node 509 and the second polarity node 511. The charge circuit 717 includes a transistor M13 and a transistor M14. Each of the transistors M13 and M14 is biased by a bias voltage VBIAS to provide a charge to the first polarity node 509 and the second polarity node 511. The differential comparator 700 also includes a set of cross-coupled pairs of transistors 703. The set of cross-coupled pairs of transistors 703 includes NMOS transistors M9 and M10 as well as PMOS transistors M11 and M12.

A gate of the PMOS transistor M11 is coupled to a drain of each of an NMOS transistor M10 and a PMOS transistor M12. A gate of the PMOS transistor M12 is coupled to a drain of each of an NMOS transistor M9 and a PMOS transistor M11. A source of each of the PMOS transistors M11 and M12 is respectively coupled to the first polarity node 509 and the second polarity node 511 to receive a voltage supply from the charge circuit 717. A gate of the NMOS transistor M9 is coupled to a drain of each of the NMOS transistor M10 and the PMOS transistor M12. A gate of the NMOS transistor M10 is coupled to a drain of each of the NMOS transistor M9 and the PMOS transistor M11.

The differential comparator 700 further includes a clocked circuit 723 that includes the NMOS transistor M7 coupled to the NMOS transistors M1 and M2 and an NMOS transistor M8 coupled to the NMOS transistors M9 and M10 of the cross-coupled pair of transistors 703. A source of each of the NMOS transistors M1 and M2 is coupled to ground 308 via the NMOS transistor M7. For example, the source of each of the NMOS transistors M1 and M2 may be coupled to a dynamic node 719. In some aspects, the dynamic node 719 may provide a ground reference for the differential comparator 700. For example, the clocked circuit 723 receives a clock signal CLK and selectively sets a voltage level at the dynamic node 719 in response to receiving the clock signal CLK. In some implementations, the clocked circuit 723 may selectively bias the voltage level of the dynamic node 719 to ground 308 (or higher).

Similarly, a source of each of the NMOS transistors M9 and M10 is coupled to the ground 308 via the NMOS transistor M8. For example, the source of each of the NMOS transistors M9 and M10 may be coupled to a dynamic node 721. The clocked circuit 723 may also selectively bias the voltage level of the dynamic node 721. The circuit in FIG. 7 can work at a lower supply voltage compared to that of FIG. 5.

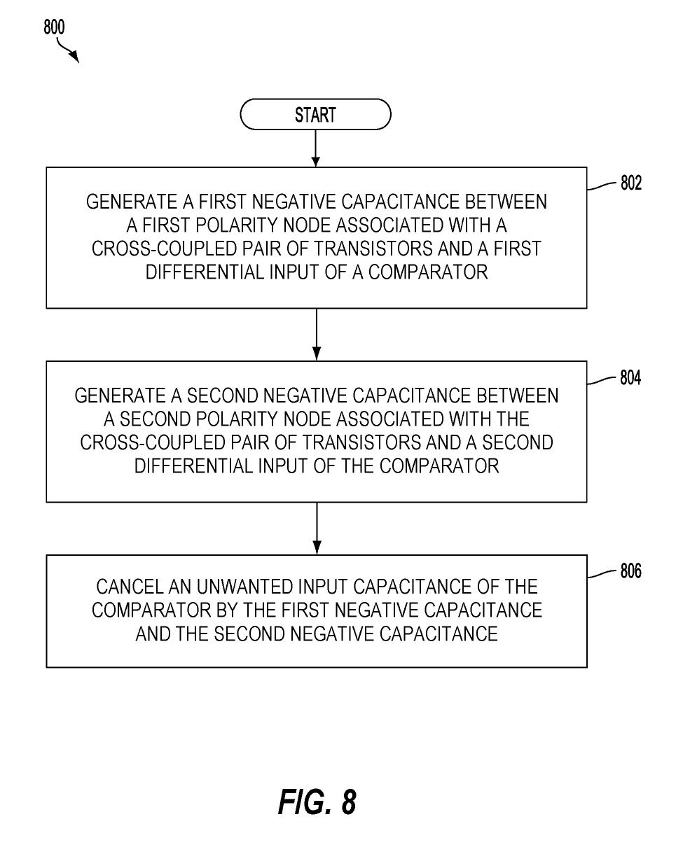

FIG. 8 depicts a simplified flowchart of a noise reduction method 800 for a comparator of a successive approximation register analog-to-digital converter (SAR ADC). At block 802, a first negative capacitance between a first polarity node associated with a cross-coupled pair of transistors and a first differential input of the comparator is generated. At block 804, a second negative capacitance between a second polarity node associated with the cross-coupled pair of transistors and a second differential input of the comparator is generated. At block 806, an unwanted input capacitance of the comparator is cancelled by the first negative capacitance and the second negative capacitance.

According to one aspect of the present disclosure, the comparator includes means for generating a first negative capacitance and means for generating a second negative capacitance. The first negative capacitance generating means may, for example, be the first metal oxide semiconductor (MOS) varactor CV1 and/or the cross-coupled pair of transistors 403 or 703. The second negative capacitance generating means may be, for example, the second metal oxide semiconductor (MOS) varactor CV2 and/or the cross-coupled pair of transistors 403 or 703. In another aspect, the aforementioned means may be any module or any apparatus or material configured to perform the functions recited by the aforementioned means.

FIG. 9 is a block diagram showing an exemplary wireless communication system in which a configuration of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925A, 925B, and 925C that include the disclosed comparator. It will be recognized that other devices may also include the disclosed comparator, such as the base stations, switching devices, and network equipment. FIG. 9 shows forward link signals 980 from the base station 940 to the remote units 920, 930, and 950 and reverse link signals 990 from the remote units 920, 930, and 950 to base station 940.

In FIG. 9, remote unit 920 is shown as a mobile telephone, remote unit 930 is shown as a portable computer, and remote unit 950 is shown as a fixed location remote unit in a wireless local loop system. For example, a remote unit may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieves data or computer instructions, or combinations thereof. Although FIG. 9 illustrates remote units according to the aspects of the disclosure, the disclosure is not limited to these exemplary illustrated units. Aspects of the disclosure may be suitably employed in many devices, which include the comparator.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, and composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

What is claimed is:

1. A comparator, comprising:
a cross-coupled pair of transistors including a first polarity node and a second polarity node of a different polarity;
a first input transistor and a second input transistor arranged in a differential configuration, a gate of the first input transistor coupled to a first array of capacitors, a gate of the second input transistor coupled to a second array of capacitors;
a first negative capacitance device coupled between the gate of the first input transistor and the first polarity node; and
a second negative capacitance device coupled between the gate of the second input transistor and the second polarity node.

2. The comparator of claim 1, in which the first polarity node comprises a positive gain node and the second polarity node comprises a negative gain node.

3. The comparator of claim 1, in which the first negative capacitance device and the second negative capacitance device are configured to cancel an input capacitance of the comparator.

4. The comparator of claim 3, in which the input capacitance comprises a gate-to-source capacitance of the first input transistor and/or the second input transistor.

5. The comparator of claim 1, in which each of the first negative capacitance device and the second negative capacitance device comprises a metal oxide semiconductor (MOS) capacitor, a metal insulator metal capacitor (MIMCAP), or a metal oxide metal capacitor (MOMCAP).

6. The comparator of claim 5, in which the MOS capacitor comprises a metal oxide semiconductor varactor (MOSVAR).

7. The comparator of claim 1, further comprising a charge circuit coupled to the first polarity node and the second polarity node.

8. The comparator of claim 1, further comprising a first dynamic node and a second dynamic node, the first input transistor and the second input transistor are coupled between the first dynamic node and the first polarity node and the second polarity node.

9. The comparator of claim 8, in which the cross-coupled pair of transistors are coupled between the second dynamic node and the first polarity node and the second polarity node.

10. A comparator, comprising:
a cross-coupled pair of transistors including a first polarity node and a second polarity node of a different polarity;
a first input transistor and a second input transistor arranged in a differential configuration, a gate of the first input transistor coupled to a first array of capacitors, a gate of the second input transistor coupled to a second array of capacitors;
means for generating a first negative capacitance, the first negative capacitance generating means coupled between the gate of the first input transistor and the first polarity node; and
means for generating a second negative capacitance, the second negative capacitance generating means coupled between the gate of the second input transistor and the second polarity node.

11. The comparator of claim 10, in which the first polarity node comprises a positive gain node and the second polarity node comprises a negative gain node.

12. The comparator of claim 10, in which the first negative capacitance generating means and the second negative capacitance generating means are for cancelling an input capacitance of the comparator.

13. The comparator of claim 12, in which the input capacitance comprises a gate-to-source capacitance of the first input transistor and/or the second input transistor.

14. The comparator of claim 10, in which each of the first negative capacitance generating means and the second negative capacitance generating means comprises a metal oxide semiconductor (MOS) capacitor, a metal insulator metal capacitor (MIMCAP), or a metal oxide metal capacitor (MOMCAP).

15. The comparator of claim 14, in which the MOS capacitor comprises a metal oxide semiconductor varactor (MOSVAR).

16. The comparator of claim 10, further comprising a charge circuit coupled to the first polarity node and the second polarity node.

17. The comparator of claim 10, further comprising a first dynamic node and a second dynamic node, the first input transistor and the second input transistor are coupled between the first dynamic node the first polarity node and the second polarity node.

18. The comparator of claim 17, in which the cross-coupled pair of transistors are coupled between the second dynamic node and the first polarity node and the second polarity node.

19. A noise reduction method for a comparator, comprising:
generating a first negative capacitance between a first polarity node associated with a cross-coupled pair of transistors and a first differential input of the comparator;
generating a second negative capacitance between a second polarity node associated with the cross-coupled pair of transistors and a second differential input of the comparator, the second polarity node having a different polarity than the first polarity node; and
cancelling an unwanted input capacitance of the comparator by the first negative capacitance and the second negative capacitance.

20. The noise reduction method of claim 19, further comprising charging the first polarity node and the second polarity node by a charge circuit.
